(19) United States
(12) Patent Application Publication
(10) Pub. No.: US 2017/0367204 A1
(43) Pub. Date: Dec. 21, 2017

(54) HERMETIC STRUCTURE AND METHOD OF MANUFACTURING THE SAME

(71) Applicant: Yokogawa Electric Corporation, Tokyo (JP)

(72) Inventor: Yukimitsu SEKIMORI, Tokyo (JP)

(73) Assignee: Yokogawa Electric Corporation, Tokyo (JP)

(21) Appl. No.: 15/622,239

(22) Filed: Jun. 14, 2017

(30) Foreign Application Priority Data
Jun. 15, 2016 (JP) 2016-119189

(51) Int. Cl. H05K 5/06

(52) U.S. Cl. CPC H05K 5/06

(57) ABSTRACT

A hermetic structure includes a hermetic body having a through-hole passing through a high pressure side and a low pressure side, the through-hole having a tapered portion whose diameter increases from the low pressure side toward the high pressure side, a conductor inserted through the through-hole, a protector component fit in the tapered portion, the protector component having a hole for inserting the conductor, and a glass member provided in the through-hole, on the low pressure side from the protector component, so as to seal the conductor.

### CROSS-REFERENCE TO RELATED APPLICATION

The present application claims priority from Japanese Patent Application No. 2016-119189 filed on Jun. 15, 2016. the entire content of which is incorporated herein by reference.

### BACKGROUND

### Technical Field

The present invention relates to a hermetic structure, and more particularly to a hermetic structure having improved pressure resistance.

### Related Art

Hermetic structures are hermetically sealed structures for completely blocking the outside air, and are used in various devices such as electronic devices and instrumentation devices. FIG. 7 is a view schematically illustrating an example of a sensor unit 310 of a pressure transmitter using hermetic structures.

As shown in FIG. 7, the sensor unit 310 having a silicon pressure sensor 350 installed therein is fixed to a capsular pressure vessel 380 having a pressure introduction portion 381 by welding. The sensor unit 310 uses a plurality of hermetic structures for taking out electric signals from the silicon pressure sensor 350. The hermetic structures which are used in the pressure transmitter need to be structures which are not damaged even if high pressure is applied to the inside of the pressure vessel 380.

The sensor unit 310 includes not only the silicon pressure sensor 350 but also a hermetic body 320 formed of a Fe—Ni based alloy or the like, a magnet 340, a ceramic member 330 holding the magnet 340 and so on, lead pins 324 inserted in through-holes 321 formed in the hermetic body 320, leads 352 electrically connecting the lead pins 324 and the silicon pressure sensor 350, and glass members 326 filling the gaps between the through-holes 321 and the lead pins 324 such that they are hermetically sealed.

In this configuration, the hermetic body 320 having the through-holes 321, the lead pins 324, and the glass members 326 constitute hermetic structure parts. FIG. 8 is a view illustrating a hermetic structure part.

As shown in FIG. 8, each hermetic structure part which has a surface X to be exposed to a high pressure and a surface Y to be exposed to atmospheric pressure is partitioned by a glass member 326. The hermetic structure parts are configured by melting a material of the glass members 326 at high temperature so as to adhere to the lead pins 324 and the hermetic body 320, thereby fixing them.

The glass members are adhered to the lead pins and the hermetic body under high temperature, thereby fixing them, such that when temperature is lose, tensile stress is suppressed from being applied to the glass members 326, whereby cracks are prevented. Specifically, materials of the glass members 326, the lead pins 324, and the hermetic body 320 are selected such that the coefficients of thermal expansion of them have a proper relation.

If a pressure is applied to the inside of the pressure vessel 380, the lead pins 324 and the surfaces X are stressed. At this time, at the boundaries between the glass members 326 and the hermetic body 320, that is, the cylindrical glass adhesion surfaces, high tensile stress occurs. If that tensile strength exceeds the fracture stress of the glass members 326 or exceeds the adhesion strength of the glass adhesion surfaces, the hermetic structures are damaged. For this reason, the value of allowable stress on the lead pins 324 and the surfaces X is generally determined according to the fracture stress of the glass members 326 or the adhesion strength of the glass adhesion surfaces, and according to that allowable stress value, the fracture pressure of the hermetic structures is determined.

The diameter (area) of the through-holes 321 of the hermetic body 320 is proportional to stress which is applied to the glass members 326 when a pressure is applied thereto, and as the diameter of the through-holes 321 increases, stress on the glass members 326 increases.

When a pressure is applied to the glass members 326 having a Young's modulus lower than those of the lead pins 324 and the hermetic body 320, the shrinkage factor of the glass members at the surfaces X increases, whereby tensile stress occurs on the glass adhesion surfaces. Also, the amount of deformation of the glass members 326 at the surfaces X depends on the length of the glass members 326 (the length from the surfaces X to the surfaces Y). If the length of the glass members 326 is set to be short, whereby the amount of deformation increases, higher tensile stress occurs on the glass adhesion surfaces.

[Patent Document 1] Japanese Patent Application Laid-Open No. 07-312244

[Patent Document 2] Japanese Patent Application Laid-Open No. 2014-175069

If the glass members 326 are lengthened in order to increase the glass adhesion area, or the diameter of the through-holes 321 of the hermetic body 320 is reduced in order to reduce pressure on the glass members 326, it is possible to improve pressure resistance to a certain degree.

In Japanese Patent Application Laid-Open No. 07-312244, there is disclosed a technology for improving pressure resistance by disposing cylindrical ceramic components 328 on the high pressure side in the through-holes 321 of the hermetic body 320, in addition to the glass members 326, and performing glass sealing using the glass members 326 as shown in FIG. 9.

If the ceramic components 328 have a Young's modulus higher than that of the glass members 326, it is possible to suppress deformation of the glass members 326. However, since all of the pressure on surfaces Z of the ceramic components is applied to the glass adhesion surfaces along the through-holes 321 of the hermetic body 320, it is impossible to achieve sufficient pressure resistance.

### SUMMARY

Exemplary embodiments of the invention provide a hermetic structure having high pressure resistance.

A hermetic structure according to an exemplary embodiment, comprises:

a hermetic body having a through-hole passing through a high pressure side and a low pressure side, the through-hole having a tapered portion whose diameter increases from the low pressure side toward the high pressure side;

a conductor inserted through the through-hole;

a protector component fit in the tapered portion, the protector component having a hole for inserting the conductor; and

a glass member provided in the through-hole, on the low pressure side from the protector component, so as to seal the conductor.

The glass member may fill a gap between the protector component and the through- hole.

A plurality of tapered portions may be formed.

The hermetic structure may further comprise:

a second glass member provided in the through-hole, on the high pressure side from the protector component so as to seal the conductor.

The protector component may be formed of a material having a Young's modulus larger than that of the hermetic body.

A method of manufacturing a hermetic structure including a hermetic body having a through-hole, which passes through the high pressure side and the low pressure side and has a tapered portion whose diameter increases from the low pressure side toward the high pressure side, and a conductor inserted through the through-hole, comprises:

fitting a protector component having a hole for inserting the conductor, in the tapered portion; and

melting a glass member disposed on the low pressure side of the through-hole, in a state where the conductor is inserted through the hole, thereby sealing the conductor.

According to the present invention, it is possible to provide a hermetic structure having high pressure resistance.

### BRIEF DESCRIPTION OF THE DRAWINGS

FIG. 1 is a view illustrating an example of a hermetic structure of an embodiment.

FIG. 2 is a view illustrating the shape of a protector component.

FIG. 3 is a view illustrating another example of the hermetic structure.

FIG. 4 is a view illustrating another example of the hermetic structure.

FIG. 5 is a view illustrating another example of the hermetic structure.

FIG. 6 is a view illustrating another example of the hermetic structure.

FIG. 7 is a view illustrating an example of a sensor unit of the related art.

FIG. 8 is a view illustrating an example of a hermetic structure of the related art.

FIG. 9 is a view illustrating an example of a hermetic structure of the related art configured to have improved pressure resistance by disposing ceramic components.

### DETAILED DESCRIPTION

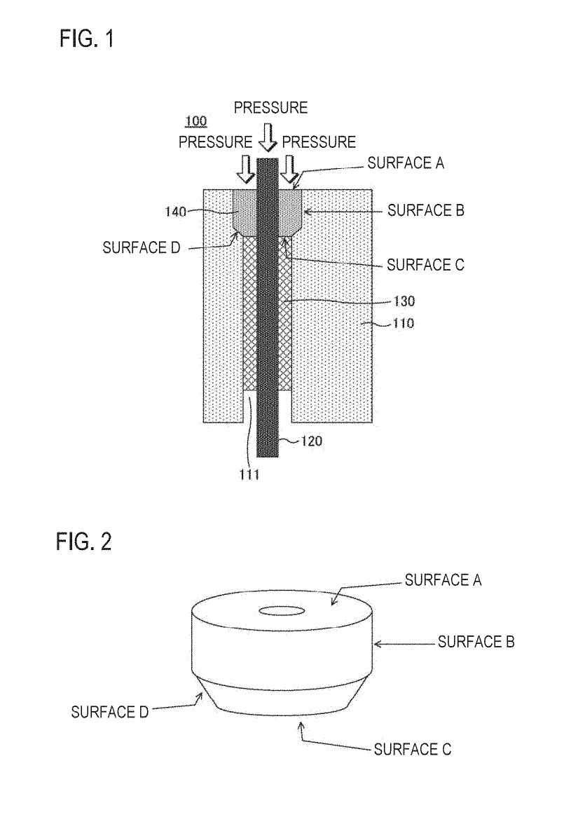

Hereinafter, an embodiment of the present invention will be described with reference to the accompanying drawings. FIG. 1 is a view illustrating an example of a hermetic structure of the present embodiment. The hermetic structure is suitable for sensors required to deal with large pressure differences and have high SA characteristics, and can be applied to various devices such as a pressure transmitter, a flow meter, a thermometer, a compressor, and a pressure tester.

As shown in FIG. 1, a hermetic structure 100 includes a hermetic body 110 having a through-hole 111 passing through the high pressure side and the low pressure side, and a lead pin 120 which is a conductor inserted through the through-hole 111. Also, in FIG. 1, the upper side is referred to as the high pressure side, and the lower side is referred to as the low pressure side. The hermetic body 110 can be formed of, for example, a Fe—Ni based alloy or the like.

The through-hole 111 of the hermetic body 110 has a tapered portion (a surface D) formed such that the diameter increases from the low pressure side toward the high pressure side. In the tapered portion of the through-hole 111, a protector component 140 in which the lead pin 120 is inserted is fit. Further, a portion of the through-hole 111 positioned on the low pressure side from the protector component 140 is filled with a glass member 130 such that the lead pin 120 is sealed.

As shown in FIG. 2, the protector component 140 is formed in a shape corresponding to the high-pressure-side end portion of the through-hole 111 including the tapered portion. In the protector component, the high-pressure-side surface, the low-pressure-side surface, the side surface, and the surface of the tapered portion are referred to as the surface A, the surface C, the surface B, and the surface D, respectively.

The glass member 130 is formed by fitting glass for sealing on the lead pin 120, and melting the glass at high temperature in the inverted state of the state shown in FIG. 1, so as to seal the hermetic body 110, the lead pin 120, and the protector component 140 at the same time. In other words, during sealing, the glass melted at high temperature flows in the gap between the protector component 140 and the hermetic body 110 and the gap between the protector component 140 and the lead pin 120, and is firmly fixed in those gaps. Also, the glass member 130 and the protector component 140 (the surface C) are firmly fixed to each other without a gap.

Therefore, the hermetic structure 100 can be manufactured by a method including a step of fitting the protector component 140 having a hole for inserting the lead pin 120, in the tapered portion of the through-hole 111, and a step of inserting the lead pin 120 through the hole, and melting the glass member disposed on the low pressure side of the through-hole 111, thereby sealing the lead pin 120.

Selection of a glass component for the glass member 130, adjustment on sealing temperature, and so on are performed such that melted glass flows in the gaps with appropriate viscosity due to action of gravity or surface tension.

Also, it is preferable to adjust the viscosity of the glass during sealing, and the sealing time, such that the glass does not protrude from the upper surface of the hermetic body 110 around the surface A. In this case, even if the hermetic structure is applied to a senor, it is possible to prevent the glass from being damaged due to contact of other components with the glass.

During manufacturing, the relation of the positions of the hermetic body 110, the lead pin 120, and the protector component 140 can be determined on the basis of the shape of the protector component 140. In other words, the protector component 140 also serves as a positioning guide, such that if the protector component 140 in which the lead pin 120 is inserted is fit in the hermetic body 110, the relation of the positions of them is determined.

The protector component 140 is formed in such a shape that the lead pin 120 is positioned at the center of the through-hole 111 so as to extend in parallel to the through-hole 111. The lead pin 120 and the through-hole 111 form a concentric structure having such a shape that the corresponding structure is strong against stress caused by distortion attributable to temperature or pressure.

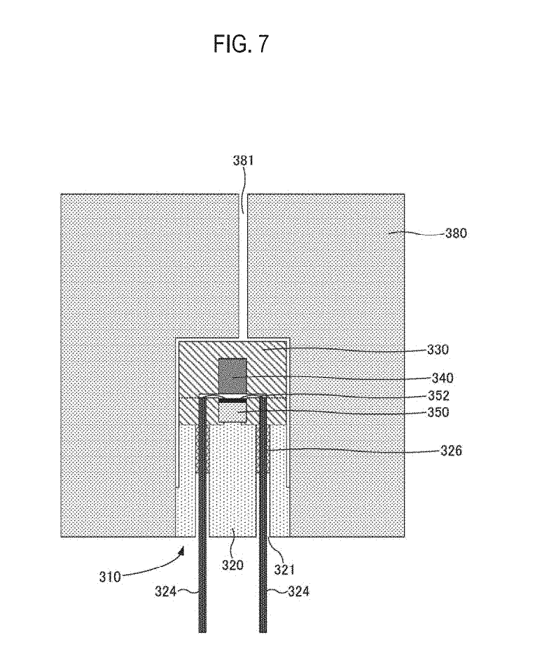

In a case of applying the hermetic structure 100 to a pressure transmitter, as the material of the hermetic body 110, a material capable of being welded to a pressure vessel (see FIG. 7) is used. In this case, a Fe—Ni based alloy having a coefficient of thermal expansion close to that of a silicon pressure sensor (see FIG. 7) around the specification temperature of the silicon pressure sensor is used.

Also, as the material of the lead pin 120, the same material as that for the hermetic body 110 can be used. In order to suppress residual stress after formation of the structure, it is preferable to select materials having coefficients of thermal expansion close to one another as the materials of the hermetic body 110, the glass member 130, the lead pin 120, and the protector component 140.

As the material of the protector component 140, an insulating material having a Young's modulus larger than that of the hermetic body 110 is used. For example, aluminum oxide (alumina) can be used. When a pressure is applied, since the Young's modulus is large, compressive stress acts from the hermetic body 110 toward the center of the through-hole 111. The compressive stress also acts on a portion of the glass filling the gap between the hermetic body 110 and the protector component 140. Therefore, the pressure resistance is improved.

As the material of the protector component 140, a material having a Young's modulus and fracture toughness larger than those of the glass member 130 is selected. Since the Young's modulus is large, it is possible to achieve an effect of reducing the amount of deformation attributable to pressure, to be smaller than that of the glass member 130, and it is possible to suppress tensile stress attributable to deformation from causing stress to be concentrated. Also, since fracture toughness is large, the protector component 140 can withstand stress higher than stress which the glass member 130 can withstand.

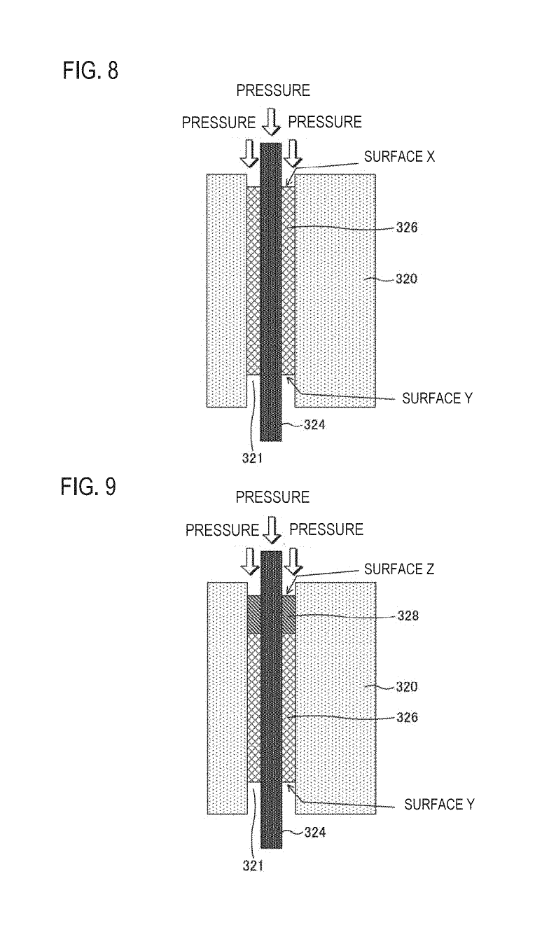

Since the area of the surface A to be a pressure receiving surface during pressurizing is larger than that of a surface X (see FIG. 8) which is a pressure receiving surface of a hermetic structure of the related art, the pressure receiving area is larger than that of the related art.

Although stress on the pressure receiving surface is high, the hermetic structure 100 of the present embodiment is a structure having high resistance to fracture stress. The reason is that the hermetic structure is a structure in which stress on the protector component 140 caused by pressurizing can be dispersed not only by the material characteristic of the protector component 140 but also by the tapered portion (the surface D) of the through-hole 111.

Since this tapered portion is formed, all of stress applied to the glass member 326 from the surface X is not applied to the glass adhesion surface which is a surface perpendicular to the pressure receiving surface, unlike in the hermetic structures (see FIG. 8) of the related art, and the stress is released toward a portion of the hermetic body 110 diagonal to the pressure receiving surface by the tapered portion (the surface D).

Also, since a portion of the protector component 140 is formed in a tapered shape, it is difficult for tensile stress to occur in the protector component 140, and thus the pressure resistance of the hermetic structure 100 is further improved.

The glass fills the gap between the protector component 140 and the lead pin 120. Since it is possible to reduce the diameter of the hole of the protector component 140 for inserting the lead pin 120, it is possible to suppress stress on the glass filling the hole of the protector component 140 when a pressure is applied, as compared to the hermetic structures of the related art.

In general, if the glass member 130 is lengthened in order to increase the glass adhesion area, or the diameter of the through-hole 111 of the hermetic body 110 is reduced in order to reduce pressure on the glass member 130, it is possible to improve the pressure resistance to a certain degree. However, if the glass member 130 is lengthened, a range in the gap between the hermetic body 110 and the lead pin 120 to be filled with a material having high permittivity is lengthened, and thus the electrostatic capacitance increases. Also, if the diameter of the through-hole 111 of the hermetic body 110 is reduced, the distance between the hermetic body 110 and the lead pin 120 shortens, and thus insulation resistance decreases. Therefore, in both of those cases, the S/N characteristic deteriorates.

In contrast with this, the hermetic structure 100 of the present embodiment is configured by forming a portion of the through-hole 111 in a tapered shape, and fitting the protector component 140 having a corresponding tapered shape in the through-hole, thereby improving the pressure resistance, without lengthening the glass member 130 or reducing the diameter of the through-hole 111. Therefore, the improvement in the pressure resistance is prevented from causing the S/N characteristic to deteriorate.

Also, in the above-described example, as the material of the hermetic body 110, a Fe—Ni based alloy is used; however, stainless materials can also be used. If a material having a coefficient of thermal expansion larger than that of the protector component 140 is used as the material of the hermetic body 110, since it is possible to make residual stress after formation of the structure act in a compression direction, it is preferable in terms of residual stress.

The protector component 140 and the lead pin 120 also have a similar relation. Therefore, in terms of residual stress, it is preferable to set the magnitude of the coefficient of thermal expansion of the hermetic body 110 so as to be larger than that of the protector component 140, and set the magnitude of the coefficient of thermal expansion of the protector component 140 so as to be larger than that of the lead pin 120.

With respect to Young's moduli, since it is desirable that compressive stress be generated when a pressure is applied, it is preferable to set the Young's modulus of the hermetic body 110 so as to be smaller than that of the protector component 140, and set the Young's modulus of the protector component 140 so as to be smaller than that of the lead pin 120.

As the material of the protector component 140, it is preferable to select a material having a coefficient of thermal expansion close to those of the materials of the hermetic body 110 and the lead pin 120, having a Young's modulus, fracture toughness, and insulation resistance larger than those of the materials of the hermetic body and the lead pin, having permittivity lower than those of the materials of the hermetic body and the lead pin, and having excellent workability. Besides aluminum oxide, for example, ceramic materials such as sapphire, zirconia, silicon nitride, silicon carbide, and aluminum nitride may be used.

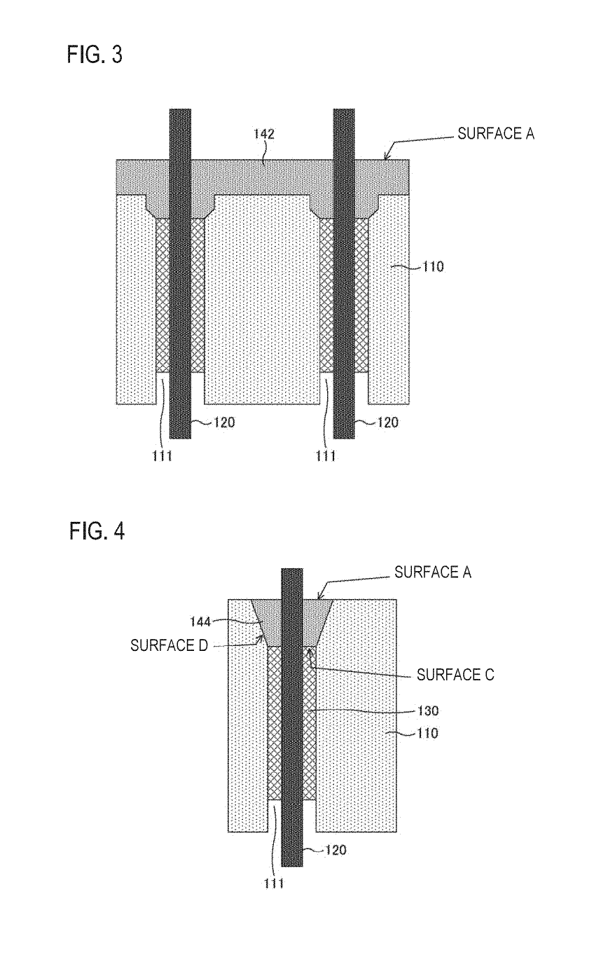

Also, in the above-described example, the protector component 140 is fit in the tapered portion of one through-hole 111. However, as shown in FIG. 3, a protector component 142 having such a shape that the protector component can be fit in a plurality of through-holes 111 may be used.

In this case, it is possible to form a plurality of hermetic structures at a time. Also, it is possible to reduce an area where steps are formed by the surface A and the hermetic body 110, and it becomes possible to suppress dead space in a case of using a combination of hermetic structures and other components, and it also becomes easy to form lead pins 120 and the protector component 142 on the same plane.

The through-hole 111 and the protector component 140 need only to have tapered portions (the surface D) diagonal to the pressure receiving surface, and thus may have a shape having no surface B perpendicular to the pressure receiving surface, for example, like a protector component 144 shown in FIG. 4. Also, the surface C may be curved.

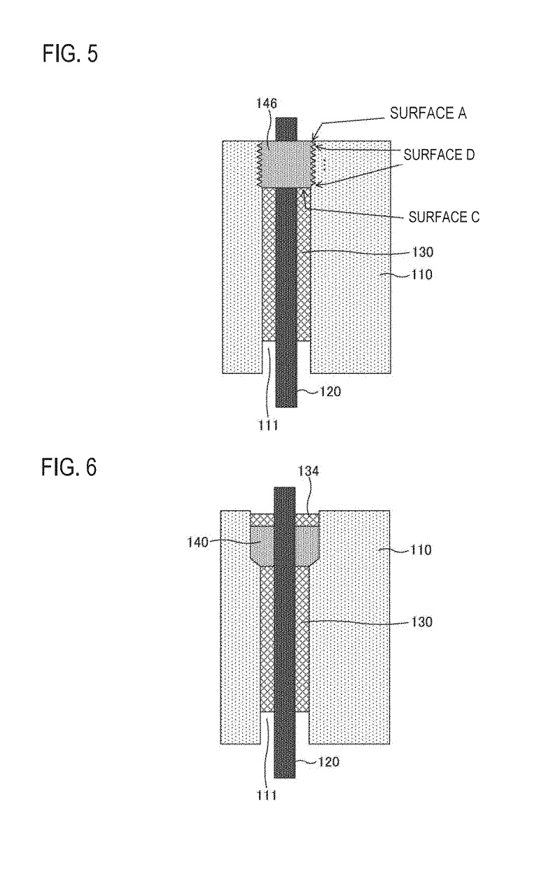

A plurality of tapered portions may be formed. For example, as shown in FIG. 5, a protector component 146 having a screw structure can be fit in the hermetic body 110. In this case, since a plurality of tapered portions is substantially formed such that the diameter increases from the low pressure side toward the high pressure side, it is possible to increase the area of the tapered surfaces. Therefore, it is possible to further release stress which is generated when a pressure is applied, in directions diagonal to the pressure receiving surface, and thus it is possible to improve the pressure resistance. In this case, since concentration of stress on some portions is prevented by the machining accuracy and surface roughness of the screw structure, it is preferable to fill the gap between the screw structure and the hermetic body with the glass for sealing.

As methods of filling the gap between the protector component 140, 142, or 144 and the hermetic body 110, there are a method of using a glass material having low viscosity to perform glass sealing under high temperature, and a method of coating the surface of the protector component 140, 142, or 144 with a material which melts at the glass sealing temperature, such as ceramic or glass, in advance. Coating can also be applied to the gap between the lead pin 120 and the protector component.

Also, it is possible to perform glass sealing from both of the low-pressure-side surface and high-pressure-side surface of the protector component 140 (or 142 or 144) by forming a second glass member 134 on the high pressure side from the protector component as shown in FIG. 6.

What is claimed is:

1. A hermetic structure comprising:
a hermetic body having a through-hole passing through a high pressure side and a low pressure side, the through-hole having a tapered portion whose diameter increases from the low pressure side toward the high pressure side;
a conductor inserted through the through-hole;
a protector component fit in the tapered portion, the protector component having a hole for inserting the conductor; and
a glass member provided in the through-hole, on the low pressure side from the protector component, so as to seal the conductor.

2. The hermetic structure according to claim 1, wherein:
the glass member fills a gap between the protector component and the through-hole.

3. The hermetic structure according to claim 1, wherein:
a plurality of tapered portions is formed.

4. The hermetic structure according to claim 1, further comprising:
a second glass member provided in the through-hole, on the high pressure side from the protector component so as to seal the conductor.

5. The hermetic structure according to claim 1, wherein:
the protector component is formed of a material having a Young's modulus larger the that of the hermetic body.

6. A method of manufacturing a hermetic structure including a hermetic body having a through-hole, which passes through the high pressure side and the low pressure side and has a tapered portion whose diameter increases from the low pressure side toward the high pressure side, and a conductor inserted through the through-hole, comprising:
fitting a protector component having a hole for inserting the conductor, in the tapered portion; and
melting a glass member disposed on the low pressure side of the through-hole, in a state where the conductor is inserted through the hole, thereby sealing the conductor.
